(19) United States
(12) Patent Application Publication
(10) Pub. No.: US 2025/0192728 A1
(43) Pub. Date: Jun. 12, 2025

(54) AMPLIFIER CIRCUIT

(71) Applicant: Murata Manufacturing Co., Ltd., Kyoto (JP)

(72) Inventors: Makoto ITOU, Kyoto (JP); Ikumi TOKUDA, Kyoto (JP)

(21) Appl. No.: 18/971,617

(22) Filed: Dec. 6, 2024

(30) Foreign Application Priority Data
Dec. 8, 2023 (JP) 2023-207879

(51) Int. Cl. H03F 1/26; H03F 3/187

(52) U.S. Cl. CPC H03F 1/26; H03F 3/187; H03F 2200/267; H03F 2200/451

(57) ABSTRACT

An amplifier circuit includes a first FET having a gate, a second FET and a third FET that are connected between a power supply and a reference potential along with the first FET, a substrate on which the first, second, and third FETs are formed, the first, second, and third FETs being vertically stacked and connected, respective gates of the first, second, and third FETs being disposed side by side in cross-sectional view of the substrate along a direction in which the first, second, and third FETs are vertically stacked and connected, an element isolation portion configured to isolate from each other two FETs adjacent to each other of the first, second, and third FETs, and a connection portion configured to connect a drain of one of the two FETs and a source of another one of the two FETs.

### CROSS REFERENCE TO RELATED APPLICATION

This application claims priority from Japanese Patent Application No. 2023-207879 filed on Dec. 8, 2023. The content of this application is incorporated herein by reference in its entirety.

### BACKGROUND ART

The present disclosure relates to an amplifier circuit.

A field-effect transistor (hereinafter referred to as an FET) is used as an amplifying element in an amplifier circuit in some cases. In FETs, silicon (Si) is considered to have a lower withstand voltage than gallium arsenide (GaAs). As a technique for supporting high power supply voltages, a technique is known for vertically stacking and connecting a plurality of FETs (hereinafter referred to as a vertical-stacking connection) and dividing a power supply voltage (e.g., Japanese Unexamined Patent Application Publication No. 2019-87992).

### BRIEF SUMMARY

As disclosed in Japanese Unexamined Patent Application Publication No. 2019-87992, pressure resistance can be improved by dividing a power supply voltage. In the case of vertical-stacking connection of a plurality of FETs, the FET elements need to be isolated from each other and adjacent ones of the isolated elements need to be electrically connected to each other. For the electric connection between the adjacent elements, a via hole is provided. However, parasitic capacitances occur at via holes each provided between the elements. As the number of vertical-stacking connections increases, parasitic capacitances due to via holes affect the characteristics of an amplifier circuit.

The present disclosure has been made in view of the above description and provides an amplifier circuit with which the effect of a parasitic capacitance on characteristics can be suppressed.

An amplifier circuit according to an aspect of the present disclosure includes a first field-effect transistor (FET) having a gate to which an input signal is applied, a second FET and a third FET that are connected between a power supply and a reference potential along with the first FET, a substrate on which the first FET, the second FET, and the third FET are formed, the first FET, the second FET, and the third FET being vertically stacked and connected, respective gates of the first FET, the second FET, and the third FET being disposed side by side in cross-sectional view of the substrate along a direction in which the first FET, the second FET, and the third FET are vertically stacked and connected, an element isolation portion configured to isolate from each other two FETs adjacent to each other of the first FET, the second FET, and the third FET, and a connection portion configured to electrically connect a drain of one of the two FETs isolated by the element isolation portion and a source of another one of the two FETs. The element isolation portion is provided between adjacent FETs of the first FET, the second FET, and the third FET, the adjacent FETs being located between the second FET and the power supply.

According to the present disclosure, the effect of a parasitic capacitance on characteristics can be suppressed in an amplifier circuit.

### BRIEF DESCRIPTION OF THE DRAWINGS

FIG. 1 is a circuit diagram illustrating an amplifier circuit according to a comparative example;

FIG. 2 is a diagram illustrating an exemplary layout of the amplifier circuit according to the comparative example;

FIG. 3 is a partial cross-sectional view of the amplifier circuit according to the comparative example;

FIG. 4 is a circuit diagram illustrating an amplifier circuit according to a first embodiment;

FIG. 5 is a diagram illustrating an exemplary layout of the amplifier circuit according to the first embodiment;

FIG. 6 is a partial cross-sectional view of the amplifier circuit according to the first embodiment;

FIG. 7 is a circuit diagram illustrating an amplifier circuit according to a second embodiment;

FIG. 8 is a diagram illustrating an exemplary layout of the amplifier circuit according to the second embodiment; and

FIG. 9 is a partial cross-sectional view of the amplifier circuit according to the second embodiment.

### DESCRIPTION OF THE PREFERRED EMBODIMENTS

Embodiments of the present disclosure will be described in detail below with reference to drawings. In the following description of each of the embodiments, the same reference numerals are given to the same or equivalent components as those in other embodiments, and the description thereof will be simplified or omitted. The present disclosure is not limited to the embodiments. The constituent elements of each of the embodiments include those that can be easily replaced by a person skilled in the art or those that are substantially the same. Note that configurations to be described below can be combined as appropriate. The configurations can be omitted, replaced, or changed without necessarily departing from the gist of the disclosure.

First, a comparative example will be described below for ease of understanding of the embodiments.

### COMPARATIVE EXAMPLE

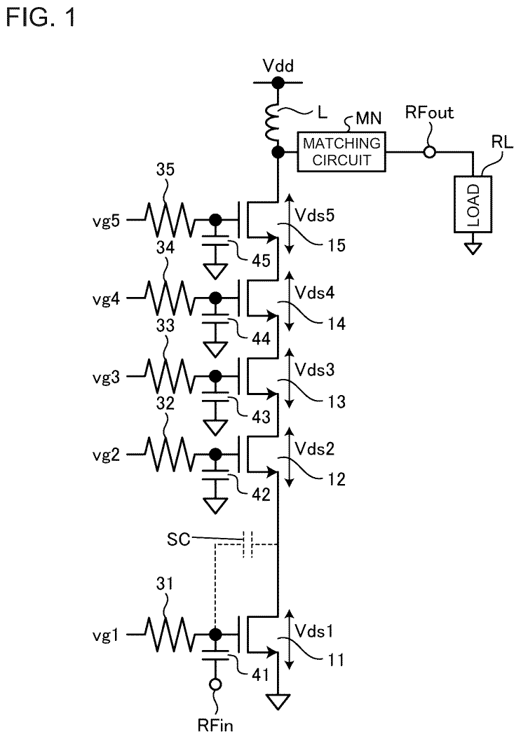

FIG. 1 is a circuit diagram illustrating an amplifier circuit according to a comparative example. FIG. 1 is a diagram describing the case where a power amplifier (hereinafter referred to as a PA in some cases) is formed with field-effect transistors (FETs). An FET is a voltage-controlled element that is controlled in accordance with a voltage applied to the gate thereof. An FET used in a silicon on insulator (SOI) complementary metal-oxide-semiconductor (CMOS) PA is subjected to a miniaturization process for improvement of performance (e.g., a cutoff frequency ft and a mutual conductance gm) of the FET.

A configuration is considered in which a plurality of FETs are vertically stacked and connected (hereinafter referred to as a vertical-stacking connection) between a power supply Vdd and a reference potential. FIG. 1 is a diagram illustrating an example of the vertical-stacking connection of a plurality of FETs. FIG. 1 illustrates the five-stage vertical-stacking connection of five FETs, that is, a configuration in which the five FETs are stacked in five stages. Referring to FIG. 1, FETs 11, 12, 13, 14, and 15 are vertically stacked and connected between the reference potential and the power supply Vdd. The reference potential is, for example, a ground potential. In the vertical-stacking connection illustrated in FIG. 1, the drain and source of the consecutively connected FETs which are adjacent to each other are connected.

Resistors 31, 32, 33, 34, and 35 are connected to the gates of the FETs 11, 12, 13, 14, and 15, respectively. Capacitors 42, 43, 44, and 45 are provided between the gates of the FETs 12, 13, 14, and 15 and the reference potential, respectively. The gate of the FET 11 is connected to an input terminal RFin via a capacitor 41. The capacitor 41 is provided to cut the direct-current component of a signal input to the input terminal RFin. A choke coil L is connected between the FET 15 and the power supply Vdd. An output terminal RFout is connected between the FET 15 and the choke coil L via a matching circuit MN. A load RL is connected to the output terminal RFout.

The source-to-drain voltage of the FET 11 is defined as a voltage Vds1, the source-to-drain voltage of the FET 12 is defined as a voltage Vds2, the source-to-drain voltage of the FET 13 is defined as a voltage Vds3, the source-to-drain voltage of the FET 14 is defined as a voltage Vds4, and the source-to-drain voltage of the FET 15 is defined as a voltage Vds5. To prevent the FETs 11, 12, 13, 14, and 15 from being broken, the values of the voltages Vds1, Vds2, Vds3, Vds4, and Vds5 need to be lower than or equal to a withstand voltage at the time of the maximum value of the power supply Vdd. Accordingly, there is the need to control the voltage values of biases vg1, vg2, vg3, vg4, and vg5 to be applied to the respective gates to prevent the respective source-to-drain voltages from exceeding the withstand voltage.

The power supply Vdd is a variable power supply, and does not have a fixed voltage value but a variable voltage value. The choke coil L is connected between the power supply Vdd and the power-supply-Vdd side of the FET 15 that is nearest to power supply Vdd of the FETs 11 to 15 that are vertically stacked and connected. The output terminal RFout is connected between choke coil L and the FET 15 via the matching circuit MN. The load RL is connected to the output terminal RFout. The biases vg1, vg2, vg3, vg4, and vg5 are applied to the gates of the FETs 11, 12, 13, 14, and 15 via the resistors 31, 32, 33, 34, and 35, respectively.

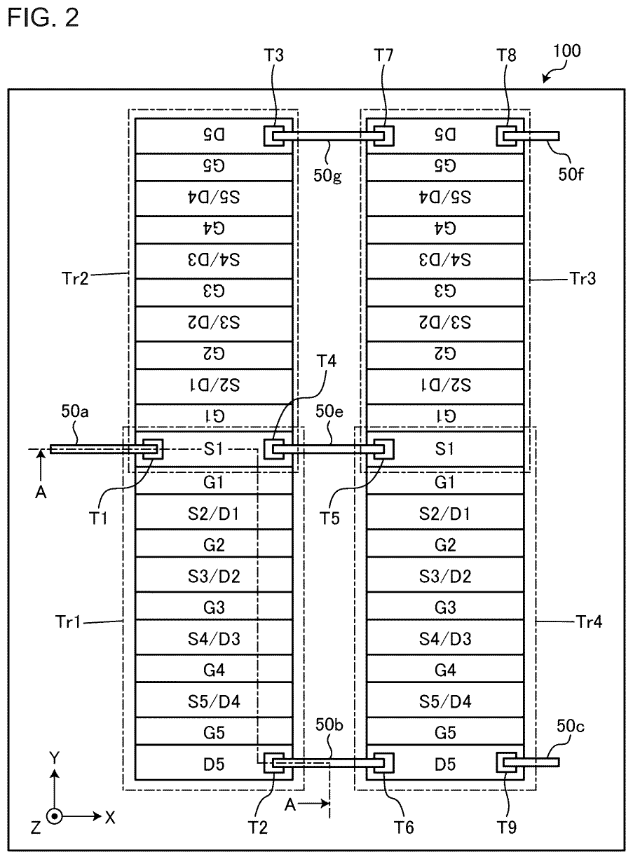

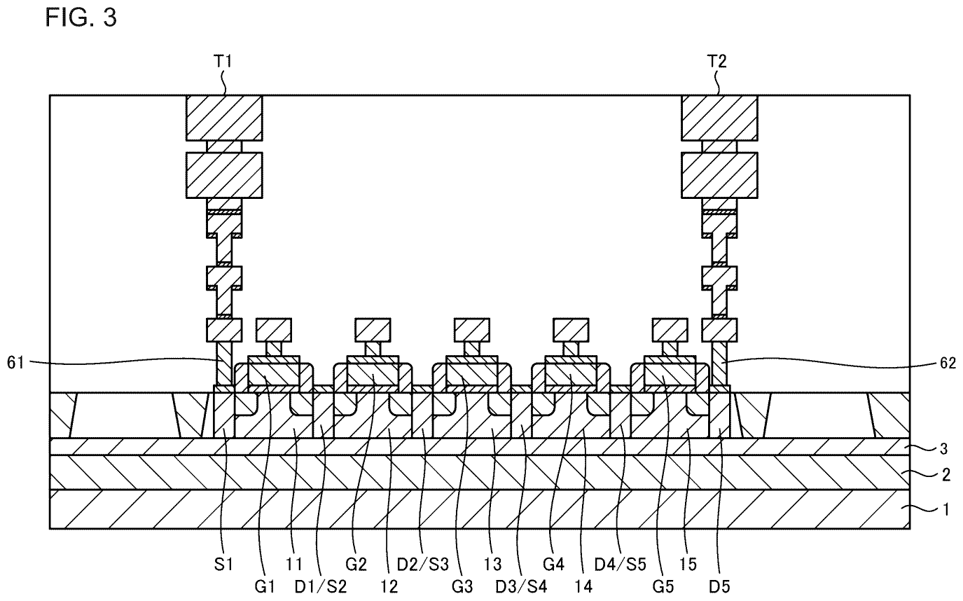

FIG. 2 is a diagram illustrating an exemplary layout of an amplifier circuit 100 according to the comparative example illustrated in FIG. 1. FIG. 2 is a plan view of the amplifier circuit 100 according to the comparative example illustrated in FIG. 1. FIG. 3 is a partial cross-sectional view of the amplifier circuit 100 according to the comparative example illustrated in FIG. 2 taken along line A-A in FIG. 2.

Referring to FIG. 2, the amplifier circuit 100 according to the present example includes four transistor blocks Tr1, Tr2, Tr3, and Tr4. Each transistor block includes a five-stage vertical-stacking connection as described with reference to FIG. 1. That is, the amplifier circuit 100 according to the present example includes the transistor blocks Tr1, Tr2, Tr3, and Tr4 each including a five-stage vertical-stacking connection.

The transistor block Tr1 will be focused on. In the block Tr1, a source S1, a gate G1, a drain D1, a source S2, a gate G2, a drain D2, a source S3, a gate G3, a drain D3, a source S4, a gate G4, a drain D4, a source S5, a gate G5, and a drain D5 are arranged in the Y direction in FIG. 2. Each of the portions arranged in the Y direction extends in the X direction. In the transistor blocks Tr2, Tr3, and Tr4, each of the portions arranged in the Y direction in FIG. 2 similarly extends in the X direction. In FIG. 2, the Z direction orthogonal to the X direction and the Y direction corresponds to the thickness direction of a substrate of the amplifier circuit 100.

The drain D1 and the source S2 of two adjacent FETs of the arranged portions illustrated in FIG. 2 are a common terminal and are denoted as “D1/S2” in FIG. 2. That is, the drain D1 and the source S2 are not separate terminals but the same terminal. The drain D2 and the source S3 of two adjacent FETs are similarly a common terminal and are denoted as “D2/S3” in FIG. 2. The drain D3 and the source S4 of two adjacent FETs are similarly a common terminal and are denoted as “D3/S4” in FIG. 2. The drain D4 and the source S5 of two adjacent FETs are similarly a common terminal and are denoted as “D4/S5” in FIG. 2. In the other blocks Tr2, Tr3, and Tr4 in FIG. 2, respective portions are similarly arranged in the Y direction and each of the portions arranged in the Y direction similarly extends in the X direction like in the transistor block Tr1. In the present example, the source S1 of the block Tr1 and the source S1 of the block Tr2 are common. The source S1 of the block Tr3 and the source S1 of the block Tr4 are common.

Electrodes T1 and T4 are connected to the source S1 of the blocks Tr1 and Tr2. An electrode T2 is connected to the drain D5 of the block Tr1. An electrode T3 is connected to the drain D5 of the block Tr2. An electrode T5 is connected to the source S1 of the blocks Tr3 and Tr4. Electrodes T7 and T8 are connected to the drain D5 of the block Tr3. Electrodes T6 and T9 are connected to the drain D5 of the block Tr4.

One end of a wiring line 50a is connected to the electrode T1. One end of a wiring line 50b is connected to the electrode T2. The other end of the wiring line 50b is connected to the electrode T6. One end of a wiring line 50e is connected to the electrode T4. The other end of the wiring line 50e is connected to the electrode T5. One end of a wiring line 50g is connected to the electrode T3. The other end of the wiring line 50g is connected to the electrode T7. One end of a wiring line 50f is connected to the electrode T8. One end of a wiring line 50c is connected to the electrode T9.

Referring to FIG. 3, the amplifier circuit 100 includes a p-type silicon substrate 1, a trap-rich layer 2 formed on the substrate 1, and an oxide film 3 formed on the trap-rich layer 2. On the oxide film 3, the FETs 11, 12, 13, 14, and 15 are formed. An upward direction in FIG. 3 corresponds to the Z direction in FIG. 2.

In FIG. 3, the FETs 11, 12, 13, 14, and 15 are arranged in a direction along the dash-dot line A-A in FIG. 2. Referring to FIG. 3, the source, gate, and drain of the FET 11 are denoted as “S1”, “G1”, and “D1”, respectively. The source, gate, and drain of the FET 12 are denoted as “S2”, “G2”, and “D2”, respectively. The source, gate, and drain of the FET 13 are denoted as “S3”, “G3”, and “D3”, respectively. The source, gate, and drain of the FET 14 are denoted as “S4”, “G4”, and “D4”, respectively. The source, gate, and drain of the FET 15 are denoted as “S5”, “G5”, and “D5”, respectively.

A via hole 61 is connected to the source S1 of the FET 11. Above the via hole 61, the electrode T1 is provided. A via hole 62 is connected to the drain D5 of the FET 15. Above the via hole 62, the electrode T2 is provided. In the amplifier circuit 100 illustrated in FIG. 3, an element isolation portion to be described below is not provided between the stages of the FETs 11, 12, 13, 14, and 15.

Referring back to FIG. 1, the amplifier circuit 100 sequentially performs an amplification operation upon the FET 11 in the undermost stage of the five-stage vertical-stacking connection to the FET 15 in the uppermost stage. That is, the amplifier circuit 100 performs an amplification operation in which the amplification output of a preceding stage is received as an input, is amplified, and is output to a subsequent stage.

A parasitic capacitance generated at the terminal of an FET in each stage affects the operation of an FET in a subsequent stage in some cases. For example, a parasitic capacitance SC generated between the gate of the FET 11 in the first stage and the common terminal functioning as the drain of the FET 11 in the first stage and the source of the FET 12 in the second stage may affect the phases of amplification outputs of the FETs in the second and subsequent stages. The changes of the phases due to the parasitic capacitance cause the degradation of modulation accuracy. In order to reduce the effect of the parasitic capacitance, element isolation between the adjacent FET stages is considered. However, when element isolation between each stage and a stage adjacent to the stage is performed, a via hole and a wiring line for the electric connection between the isolated elements are needed. A parasitic capacitance generated by the via hole and the wiring line affects the characteristics of an amplifier circuit.

### First Embodiment

### Circuit Configuration

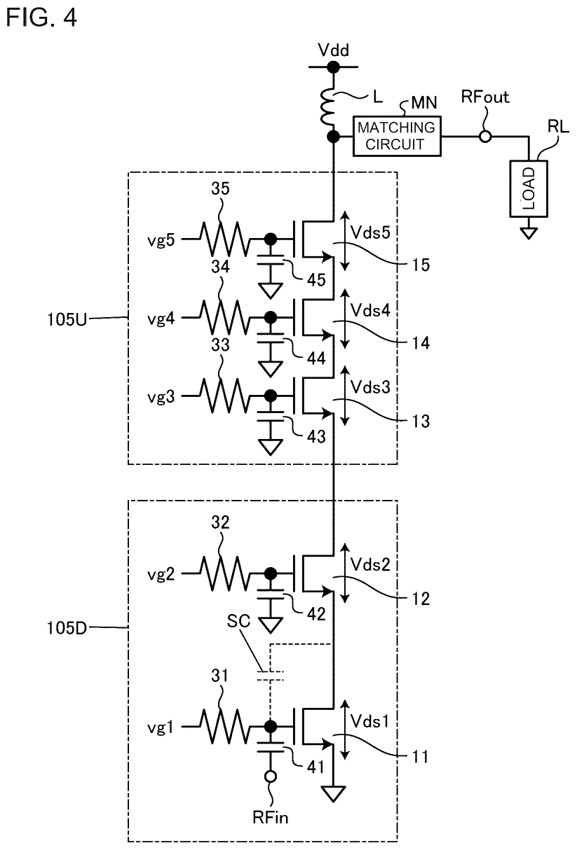

FIG. 4 is a circuit diagram illustrating an amplifier circuit 100a according to a first embodiment. Referring to FIG. 4, the amplifier circuit 100a has the configuration in which FETs are vertically stacked in five stages like the amplifier circuit 100 according to the comparative example. The amplifier circuit 100a includes a lower stage portion 105D of the stack and an upper stage portion 105U of the stack. The lower stage portion 105D includes the FET 11 in the first stage and the FET 12 in the second stage. The upper stage portion 105U includes the FET 13 in the third stage, the FET 14 in the fourth stage, and the FET 15 in the fifth stage. Between the lower stage portion 105D and the upper stage portion 105U, that is, between the FET 12 in the second stage and the FET 13 in the third stage, an element isolation portion to be described below is provided.

A capacitor 42 is connected between the gate of the FET 12 and a reference potential. A capacitor 43 is connected between the gate of the FET 13 and the reference potential. It is desired that the capacitance value of the capacitor 42 be larger than that of the capacitor 43. The capacitor 42 corresponds to a first capacitor according to the present disclosure. The capacitor 43 corresponds to a second capacitor according to the present disclosure. The on-resistance of the upper stage portion 105U differs from that of the lower stage portion 105D, and is lower than that of the lower stage portion 105D. That is, the on-resistance of the FET 13 in the third stage is lower than that of the FET 12 in the second stage.

### Layout

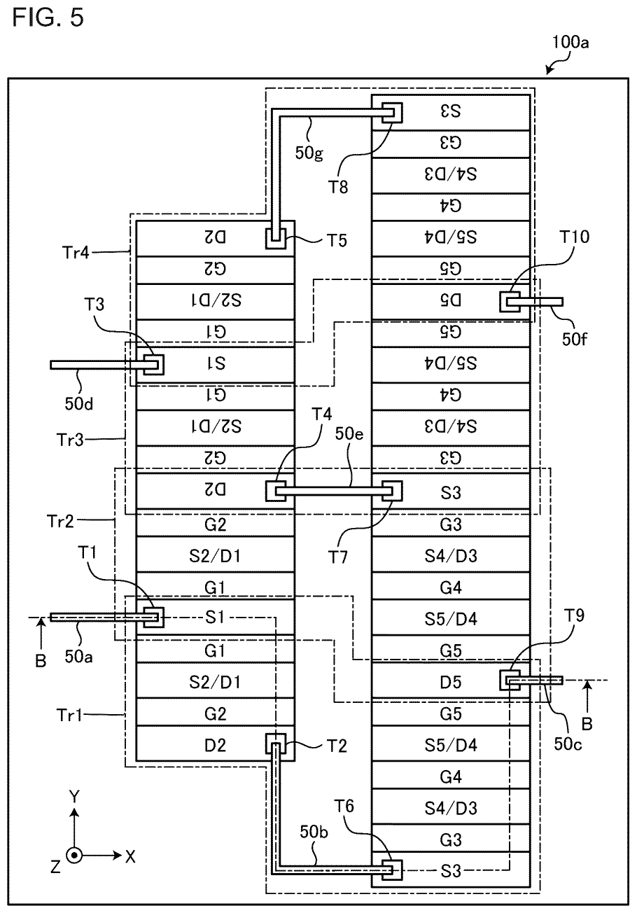

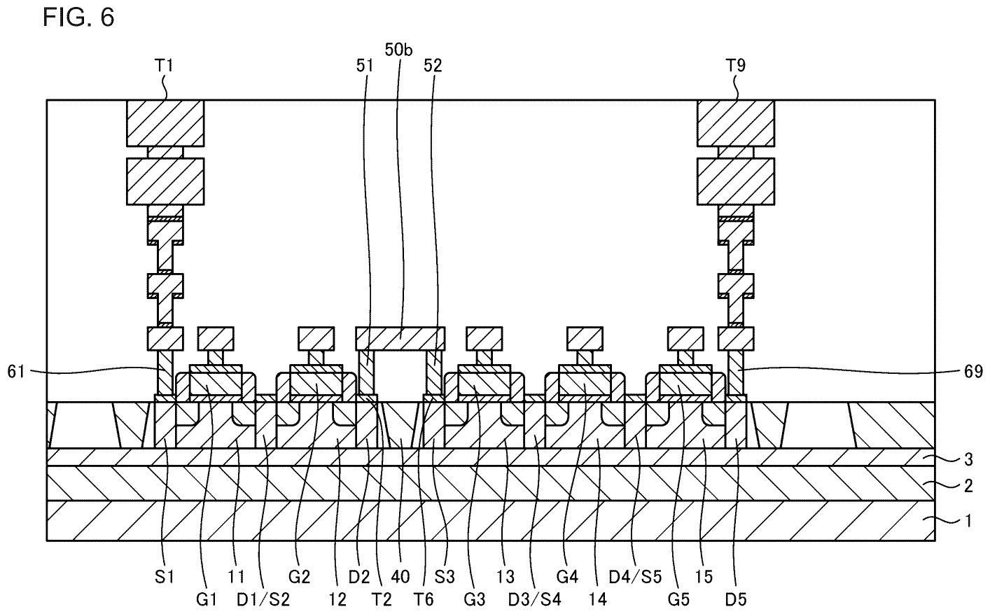

FIG. 5 is a diagram illustrating an exemplary layout of the amplifier circuit 100a according to the first embodiment illustrated in FIG. 4. FIG. 5 is a plan view of the amplifier circuit 100a according to the first embodiment illustrated in FIG. 4. FIG. 6 is a partial cross-sectional view of the amplifier circuit 100a according to the first embodiment illustrated in FIG. 5 taken along line B-B in FIG. 5.

Referring to FIG. 5, the amplifier circuit 100a includes the four transistor blocks Tr1, Tr2, Tr3, and Tr4 as is the case in FIG. 2. Each transistor block includes a five-stage vertical-stacking connection as described with reference to FIG. 4. That is, the amplifier circuit 100a according to the present embodiment includes the transistor blocks Tr1, Tr2, Tr3, and Tr4 each including a five-stage vertical-stacking connection.

The transistor block Tr1 illustrated in FIG. 5 will be focused on. As is the case illustrated in FIG. 2, in the block Tr1, the source S1, the gate G1, the drain D1, the source S2, the gate G2, and the drain D2 are arranged in the Y direction in FIG. 5, and the source S3, the gate G3, the drain D3, the source S4, the gate G4, the drain D4, the source S5, the gate G5, and the drain D5 are arranged in the Y direction in FIG. 5. In FIG. 5, the drain D2 and the source S3 are separate terminals unlike the case in FIG. 2. In the transistor blocks Tr2, Tr3, and Tr4, the drain D2 and the source S3 are similarly separate terminals.

In FIG. 5, the electrode T1 is connected to the source S1 of the blocks Tr1 and Tr2. The electrode T2 is connected to the drain D2 of the block Tr1. The electrode T6 is connected to the source S3 of the block Tr1. The electrode T9 is connected to the drain D5 of the blocks Tr1 and Tr2. The electrode T4 is connected to the drain D2 of the blocks Tr2 and Tr3. The electrode T7 is connected to the source S3 of the blocks Tr2 and Tr3. The electrode T3 is connected to the source S1 of the blocks Tr3 and Tr4. The electrode T10 is connected to the drain D5 of the blocks Tr3 and Tr4. The electrode T5 is connected to the drain D2 of the block Tr4. The electrode T8 is connected to the source S3 of the block Tr4.

In FIG. 5, one end of the wiring line 50a is connected to the electrode T1. One end of the wiring line 50b is connected to the electrode T2. The other end of the wiring line 50b is connected to the electrode T6. One end of the wiring line 50e is connected to the electrode T4. The other end of the wiring line 50e is connected to the electrode T7. One end of a wiring line 50d is connected to the electrode T3. One end of the wiring line 50g is connected to the electrode T5. The other end of the wiring line 50g is connected to the electrode T8. One end of the wiring line 50c is connected to the electrode T9. One end of the wiring line 50f is connected to the electrode T10.

Referring to FIG. 6, the drain D2 and the source S3 are separate terminals unlike the case in FIG. 3. An element isolation portion 40 is provided between the drain D2 and the source S3. The element isolation portion 40 is, for example, a shallow trench isolation (STI). By providing the element isolation portion 40, the occurrence of a leakage current between adjacent elements, that is, the FETs 12 and 13, can be prevented and pressure resistance can be ensured.

The FETs 12 and 13 are isolated from each other by the element isolation portion 40. A via hole 51 is connected to the drain D2 of the FET 12, and a via hole 52 is connected to the source S3 of the FET 13. The via holes 51 and 52 are connected to the wiring line 50b. The via holes 51 and 52 are electrically connected to each other by the wiring line 50b. That is, the wiring line 50b electrically connects the drain D2 of one of the two FETs isolated by the element isolation portion 40 and the source S3 of the other one of them. The wiring line 50b corresponds to a connection portion according to the present disclosure.

The via hole 61 is connected to the source S1 of the FET 11. Above the via hole 61, the electrode T1 is provided. A via hole 69 is connected to the drain D5 of the FET 15. Above the via hole 69, the electrode T9 is provided.

### Effects

As described above, when element isolation between each stage and a stage adjacent to the stage is performed, a via hole and a wiring line for the electric connection between the isolated elements are needed. A parasitic capacitance generated by the via hole and the wiring line affects the characteristics of an amplifier circuit. In the first embodiment, the element isolation portion 40 is provided only between the FET 12 in the second stage and the FET 13 in the third stage. As compared with the case where an element isolation portion is provided between each stage and a stage adjacent to the stage, a parasitic capacitance can be reduced and the effect of the parasitic capacitance upon the characteristics of an amplifier circuit can be reduced.

If an element isolation portion is provided between the drain of the FET 11 in the first stage and the source of the FET 12 in the second stage, the parasitic capacitance SC (see FIG. 4) occurs and affects the characteristics of the amplifier circuit. In the first embodiment, the element isolation portion 40 is provided only between the FET 12 in the second stage and the FET 13 in the third stage. Accordingly, the parasitic capacitance SC represented by a dotted line in FIG. 4 does not occur and this can lead to the reduction in parasitic capacitance. An element isolation portion may be provided between the adjacent FETs other than between the drain of the FET 11 in the first stage and the source of the FET 12 in the second stage. That is, an element isolation portion is provided between the adjacent FETs located between the FET in the second stage and the power supply Vdd.

### Second Embodiment

### Circuit Configuration

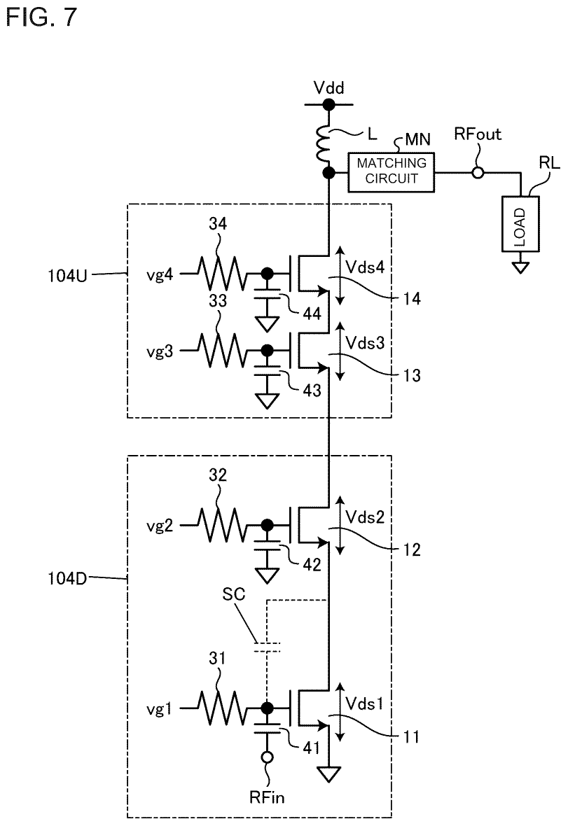

FIG. 7 is a circuit diagram illustrating an amplifier circuit 100b according to a second embodiment. Referring to FIG. 7, the amplifier circuit 100b has the configuration in which FETs are vertically stacked in four stages unlike the amplifier circuit 100 according to the comparative example and the amplifier circuit 100a according to the first embodiment. The amplifier circuit 100b includes the lower stage portion 104D of the stack and the upper stage portion 104U of the stack. The lower stage portion 104D includes the FET 11 in the first stage and the FET 12 in the second stage. The upper stage portion 104U includes the FET 13 in the third stage and the FET 14 in the fourth stage. Between the lower stage portion 104D and the upper stage portion 104U, that is, between the FET 12 in the second stage and the FET 13 in the third stage, an element isolation portion to be described below is provided. The on-resistance of the upper stage portion 104U differs from that of the lower stage portion 104D, and is lower than that of the lower stage portion 104D.

### Layout

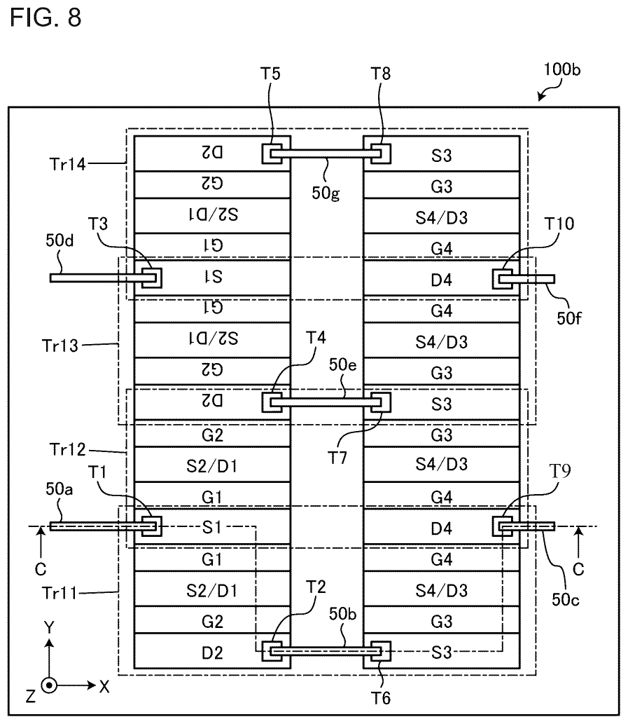

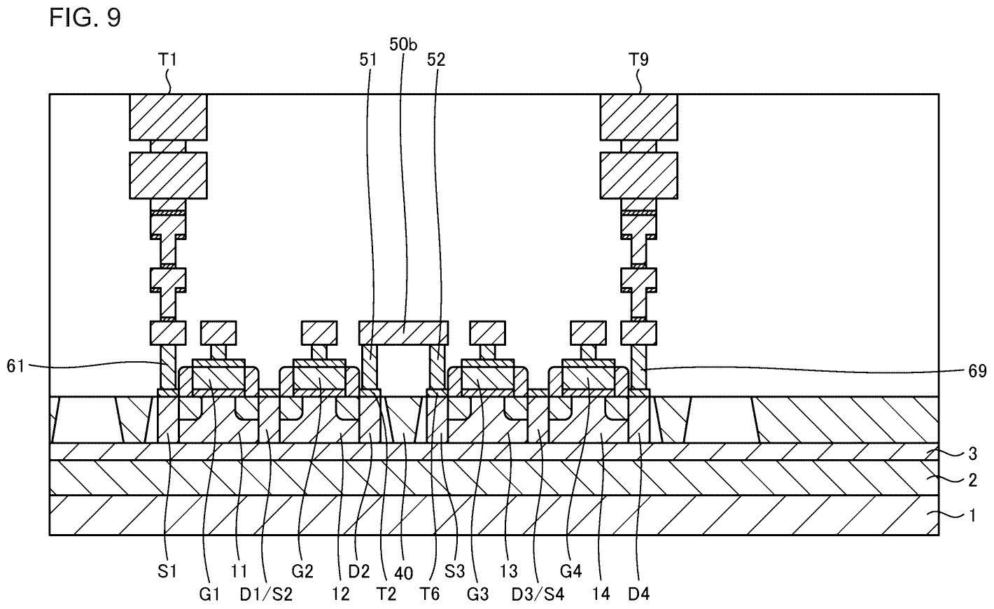

FIG. 8 is a diagram illustrating an exemplary layout of the amplifier circuit 100b according to the second embodiment illustrated in FIG. 7. FIG. 8 is a plan view of the amplifier circuit 100b according to the second embodiment illustrated in FIG. 7. FIG. 9 is a partial cross-sectional view of the amplifier circuit 100b according to the second embodiment illustrated in FIG. 8 taken along line C-C in FIG. 8.

Referring to FIG. 8, the amplifier circuit 100b includes four transistor blocks Tr11, Tr12, Tr13, and Tr14. Each transistor block includes a four-stage vertical-stacking connection as described with reference to FIG. 7. That is, the amplifier circuit 100a according to the present embodiment includes the transistor blocks Tr11, Tr12, Tr13, and Tr14 each including a four-stage vertical-stacking connection.

The transistor block Tr1l illustrated in FIG. 8 will be focused on. In the block Tr1l, the source S1, the gate G1, the drain D1, the source S2, the gate G2, and the drain D2 are arranged in the Y direction in FIG. 8, and the source S3, the gate G3, the drain D3, the source S4, the gate G4, and the drain D4 are arranged in the Y direction in FIG. 8. In FIG. 8, the drain D2 and the source S3 are separate terminals unlike the case in FIG. 2.

In FIG. 8, the electrode T1 is connected to the source S1 of the blocks Tr11 and Tr12. The electrode T2 is connected to the drain D2 of the block Tr11. The electrode T6 is connected to the source S3 of the block Tr11. The electrode T9 is connected to the drain D4 of the blocks Tr11 and Tr12. The electrode T3 is connected to the source S1 of the blocks Tr13 and Tr14. The electrode T5 is connected to the drain D2 of the block Tr14. The electrode T8 is connected to the source S3 of the block Tr14. The electrode T10 is connected to the drain D4 of the blocks Tr13 and Tr14.

In FIG. 8, one end of the wiring line 50a is connected to the electrode T1. One end of the wiring line 50b is connected to the electrode T2. The other end of the wiring line 50b is connected to the electrode T6. One end of the wiring line 50e is connected to the electrode T4. The other end of the wiring line 50e is connected to the electrode T7. One end of the wiring line 50d is connected to the electrode T3. One end of the wiring line 50g is connected to the electrode T5. The other end of the wiring line 50g is connected to the electrode T8. One end of the wiring line 50c is connected to the electrode T9. One end of the wiring line 50f is connected to the electrode T10.

Referring to FIG. 9, the drain D2 and the source S3 are separate terminals as is the case in FIG. 6. The element isolation portion 40 is provided between the drain D2 and the source S3. The element isolation portion 40 is, for example, an STI. By providing the element isolation portion 40, the occurrence of a leakage current between adjacent elements, that is, the FETs 12 and 13, can be prevented and pressure resistance can be ensured.

The FETs 12 and 13 are isolated from each other by the element isolation portion 40. As is the case in FIG. 6, the via hole 51 is connected to the drain D2 of the FET 12 and the via hole 52 is connected to the source S3 of the FET 13. The via holes 51 and 52 are connected to the wiring line 50b. The via holes 51 and 52 are electrically connected to each other by the wiring line 50b. The wiring line 50b corresponds to the connection portion according to the present disclosure.

### (Effects)

As described above, when element isolation between each stage and a stage adjacent to the stage is performed, a via hole and a wiring line for the electric connection between the isolated elements are needed. A parasitic capacitance generated by the via hole and the wiring line affects the characteristics of an amplifier circuit. In the second embodiment, the element isolation portion 40 is also provided only between the FET 12 in the second stage and the FET 13 in the third stage. As compared with the case where an element isolation portion is provided between each stage and a stage adjacent to the stage, a parasitic capacitance can be reduced and the effect of the parasitic capacitance upon the characteristics of an amplifier circuit can be reduced.

If an element isolation portion is provided between the drain of the FET 11 in the first stage and the source of the FET 12 in the second stage, the parasitic capacitance SC (see FIG. 7) occurs and affects the characteristics of the amplifier circuit. In the second embodiment, the element isolation portion 40 is provided only between the FET 12 in the second stage and the FET 13 in the third stage. Accordingly, the parasitic capacitance SC represented by the dotted line in FIG. 7 does not occur and this can lead to the reduction in parasitic capacitance. An element isolation portion may be provided between the adjacent FETs other than between the drain of the FET 11 in the first stage and the source of the FET 12 in the second stage. That is, an element isolation portion is provided between the adjacent FETs located between the FET in the second stage and the power supply Vdd.

The present disclosure can be embodied in the following aspects with regard to the description of Claims.

<1> An amplifier circuit comprising:
a first field-effect transistor (FET) having a gate to which an input signal is applied;
a second FET and a third FET that are connected between a power supply and a reference potential along with the first FET;
a substrate on which the first FET, the second FET, and the third FET are formed, the first FET, the second FET, and the third FET being vertically stacked and connected, respective gates of the first FET, the second FET, and the third FET being disposed side by side in cross-sectional view of the substrate along a direction in which the first FET, the second FET, and the third FET are vertically stacked and connected;
an element isolation portion configured to isolate from each other two FETs adjacent to each other of the first FET, the second FET, and the third FET; and
a connection portion configured to electrically connect a drain of one of the two FETs isolated by the element isolation portion and a source of another one of the two FETs,
wherein the element isolation portion is provided to be located between the second FET and the power supply.

<2> The amplifier circuit according to <1>, wherein a drain of one of two FETs adjacent to each other of the first FET, the second FET, and the third FET and a source of another one of the two FETs are a common terminal.

<3> The amplifier circuit according to <1> or <2>, wherein the element isolation portion is provided between the second FET and the third FET and isolates the second FET and the third FET from each other.

<4> The amplifier circuit according to any one of <1> to <3>, further comprising:
a first capacitor connected between the gate of the second FET and the reference potential; and
a second capacitor connected between the gate of the third FET and the reference potential,
wherein a capacitance value of the first capacitor is larger than a capacitance value of the second capacitor.

<5> The amplifier circuit according to any one of <1> to <4>, wherein an on-resistance of the third FET is lower than an on-resistance of the second FET.

What is claimed is:

1. An amplifier circuit comprising:
a first field-effect transistor (FET), a second FET, and a third FET, each of the first FET, the second FET, and the third FET being connected between a power supply and a reference potential, wherein the first FET has a gate to which an input signal is applied; and
a substrate on which the first FET, the second FET, and the third FET are formed, the first FET, the second FET, and the third FET being vertically stacked and connected on a substrate, respective gates of the first FET, the second FET, and the third FET being disposed side by side in a cross-sectional view of the substrate along a direction in which the first FET, the second FET, and the third FET are vertically stacked and connected;
wherein the substrate comprises an element isolation portion configured to isolate two adjacent FETs from each other, the two adjacent FETs being two of the first FET, the second FET, and the third FET,
wherein the substrate further comprises a connection portion of the substrate configured to electrically connect a drain of one of the two adjacent FETs and a source of another one of the two adjacent FETs, and
wherein the element isolation portion is between the two adjacent FETs, and the two adjacent FETs are located between the second FET and the power supply.

2. The amplifier circuit according to claim 1, wherein the drain of the one of the two adjacent FETs and the source of the other of the two adjacent FETs share a common terminal.

3. The amplifier circuit according to claim 1, wherein the element isolation portion is between the second FET and the third FET, and is configured to isolate the second FET and the third FET from each other.

4. The amplifier circuit according to claim 1, further comprising:
a first capacitor connected between the gate of the second FET and the reference potential; and
a second capacitor connected between the gate of the third FET and the reference potential,
wherein a capacitance value of the first capacitor is larger than a capacitance value of the second capacitor.

5. The amplifier circuit according to claim 1, wherein an on-resistance of the third FET is lower than an on-resistance of the second FET.

6. The amplifier circuit according to claim 2, wherein the element isolation portion is between the second FET and the third FET, and is configured to isolate the second FET and the third FET from each other.

7. The amplifier circuit according to claim 2, further comprising:
a first capacitor connected between the gate of the second FET and the reference potential; and
a second capacitor connected between the gate of the third FET and the reference potential,
wherein a capacitance value of the first capacitor is larger than a capacitance value of the second capacitor.

8. The amplifier circuit according to claim 2, wherein an on-resistance of the third FET is lower than an on-resistance of the second FET.
